(19) United States
(12) Patent Application Publication
(10) Pub. No.: US 2020/0127052 A1
(43) Pub. Date: Apr. 23, 2020

(54) MEMORY CELL USING SELECTIVE EPITAXIAL VERTICAL CHANNEL MOS SELECTOR TRANSISTOR

(71) Applicant: Spin Memory, Inc., Fremont, CA (US)

(72) Inventors: Andrew J. Walker, Mountain View, CA (US); Dafna Beery, Palo Alto, CA (US); Peter Cuevas, Los Gatos, CA (US); Amitay Levi, Cupertino, CA (US)

(21) Appl. No.: 16/719,790

(22) Filed: Dec. 18, 2019

Related U.S. Application Data
(63) Continuation-in-part of application No. 16/237,143, filed on Dec. 31, 2018.
Application No. 16/237,143 is a continuation-in-part of application No. 15/857,387, filed on Dec. 28, 2017, now Pat. No. 10,468,293.

(51) Int. Cl. H01L 27/24; H01L 43/08; H01L 43/12; H01L 45/00; H01L 27/22

(52) U.S. Cl. CPC H01L 27/2454; H01L 43/08; H01L 43/12; H01L 45/16; H01L 27/2463; H01L 45/1206; H01L 27/224; H01L 27/228; H01L 45/06

(57) ABSTRACT

A memory array for data recording that includes a selector transistor electrically connected with a two terminal resistive memory element such as a magnetic tunnel junction (MTJ) element. The selector transistor comprises a semiconductor column formed by selective epitaxial growth on a semiconductor surface. The semiconductor column is at least partially surrounded by a gate dielectric layer and an electrically conductive gate structure arranged such that the gate dielectric is between the electrically conducive gate structure and the semiconductor column. The selective epitaxial growth of the semiconductor column allows the semiconductor column to have a very low electrical resistance in an “on” state which allows the selector transistor to provide a high electrical current to the two terminal resistive memory element for reliable switching during data writing.

### RELATED INVENTIONS

The present invention is a Continuation in part of commonly assigned U.S. patent application Ser. No. 16/237,143 entitled “METHODS OF FORMING PERPENDICULAR MAGNETIC TUNNEL JUNCTION MEMORY CELLS HAVING VERTICAL CHANNELS,” filed Dec. 31, 2018, which in turn is a Continuation in part of, and claims priority to, U.S. patent application Ser. No. 15/857,387, filed Dec. 28, 2018, entitled “METHODS OF FORMING PERPENDICULAR MAGNETIC TUNNEL JUNCTION MEMORY CELLS HAVING VERTICAL CHANNELS,” now U.S. Pat. No. 10,468,293.

### FIELD OF THE INVENTION

The present invention relates to two terminal resistive memory and more particularly to a memory array employing a two terminal resistive memory element driven by a vertical selector channel formed by selective epitaxial semiconductor growth.

### BACKGROUND

The ever-increasing demand for data storage has led a push for the development of new and improved memory structures. Traditionally data has been stored in an array of transistors which can be employed as switches to store data as a one (1) and zero (0) memory states. Ideally, data storage systems can operate quickly, at low energy consumption and can maintain stored data over a long period of time without compromise of data integrity. Recently, researchers have looked to memory storage employing memory cells other than pure transistor storage, such as through the use of two terminal resistive switches.

Various types of two terminal resistive switches can be used to store data. One type of two terminal resistive switching technology that can be used to store data is Magnetic Random-Access Memory (MRAM). Magnetic Random-Access Memory (MRAM) is a non-volatile data memory technology that stores data using magnetoresistive cells such as Magnetoresistive Tunnel Junction (MTJ) cells. At their most basic level, such MTJ elements include first and second magnetic layers that are separated by a thin, non-magnetic layer such as a tunnel barrier layer, which can be constructed of a material such as Mg—O. The first magnetic layer, which can be referred to as a reference layer, has a magnetization that is fixed in a direction that is perpendicular to that plane of the layer. The second magnetic layer, which can be referred to as a magnetic free layer, has a magnetization that is free to move so that it can be oriented in either of two directions that are both generally perpendicular to the plane of the magnetic free layer. Therefore, the magnetization of the free layer can be either parallel with the magnetization of the reference layer or anti-parallel with the direction of the reference layer (i.e. opposite to the direction of the reference layer).

The electrical resistance through the MTJ element in a direction perpendicular to the planes of the layers changes with the relative orientations of the magnetizations of the magnetic reference layer and magnetic free layer. When the magnetization of the magnetic free layer is oriented in the same direction as the magnetization of the magnetic reference layer, the electrical resistance through the MTJ element is at its lowest electrical resistance state. Conversely, when the magnetization of the magnetic free layer is in a direction that is opposite to that of the magnetic reference layer, the electrical resistance across the MTJ element is at its highest electrical resistance state.

The switching of the MTJ element between high and low resistance states results from electron spin transfer. An electron has a spin orientation. Generally, electrons flowing through a conductive material have random spin orientations with no net spin orientation. However, when electrons flow through a magnetized layer, the spin orientations of the electrons become aligned so that there is a net aligned orientation of electrons flowing through the magnetic layer, and the orientation of this alignment is dependent on the orientation of the magnetization of the magnetic layer through which they travel. When the orientations of the magnetizations of the free and reference layer are oriented in the same direction, the majority spin of the electrons in the free layer is in the same direction as the orientation of the majority spin of the electrons in the reference layer. Because these electron spins are in generally the same direction, the electrons can pass relatively easily through the tunnel barrier layer. However, if the orientations of the magnetizations of the free and reference layers are opposite to one another, the spin of majority electrons in the free layer will be generally opposite to the majority spin of electrons in the reference layer. In this case, electrons cannot easily pass through the barrier layer, resulting in a higher electrical resistance through the MTJ stack.

Because the MTJ element can be switched between low and high electrical resistance states, it can be used as a memory element to store a bit of data. For example, the low resistance state can be read as a “0”, whereas the high resistance state can be read as a “1”. In addition, because the magnetic orientation of the magnetic free layer remains in its switched orientation without any electrical power to the element, it provides a robust, non-volatile data memory bit.

To write a bit of data to the MTJ cell, the magnetic orientation of the magnetic free layer can be switched from a first direction to a second direction that is 180 degrees from the first direction. This can be accomplished, for example, by applying a current through the MTJ element in a direction that is perpendicular to the planes of the layers of the MTJ element. An electrical current applied in one direction will switch the magnetization of the free layer to a first orientation, whereas switching the direction of the current such that it is applied in a second direction will switch the magnetization of the free layer to a second, opposite orientation. Once the magnetization of the free layer has been switched by the current, the state of the MTJ element can be read by reading a voltage across the MTJ element, thereby determining whether the MTJ element is in a “1” or “0” bit state. Advantageously, once the switching electrical current has been removed, the magnetic state of the free layer will remain in the switched orientation until such time as another electrical current is applied to again switch the MTJ element. Therefore, the recorded data bit is non-volatile in that it remains intact in the absence of any electrical power.

The magnetic memory elements can be arranged in an array of memory elements that are connected with word lines and bit lines. A source-line can provide read and write currents to the memory elements, with the individual memory elements being selected by the word line and bit line. In addition to MRAM memory systems, other types of two terminal resistive switching elements can be used in a similar manner being connected with word and bit lines to both switch the memory state of the element and to read a memory state of the element.

### SUMMARY

The present invention provides a memory array that includes a semiconductor substrate having a recess formed in its surface. A selector transistor is formed on the substrate, the selector transistor including a semiconductor column extending from the recess formed in the surface of the substrate, a gate dielectric surrounding at least a portion of the semiconductor column, and an electrically conductive gate structure arranged such that the gate dielectric is between the electrically conductive gate structure and the semiconductor column. A two terminal resistive memory element is electrically connected with the semiconductor column of the selector transistor.

The semiconductor column can be formed by selective epitaxial growth on a semiconductor substrate. The selective epitaxial growth of the semiconductor column advantageously allows the semiconductor column to have a very low electrical resistance when in an “on” state so that a large amount of electrical current can be delivered to the two terminal resistive memory element. This allows for reliable switching of the memory element during data writing.

The selective epitaxial growth of the semiconductor column can be performed by first etching a notched region into the surface of a semiconductor substrate. The semiconductor substrate is etched sufficiently to remove any oxide in the region where the semiconductor column is to be formed. The etching can be performed in such a manner as to form a beveled surface in the notched region. This has been found to result in a good mono-crystalline structure in the semiconductor channel grown thereon.

These and other features and advantages of the invention will be apparent upon reading of the following detailed description of the embodiments taken in conjunction with the figures in which like reference numeral indicate like elements throughout.

### BRIEF DESCRIPTION OF THE DRAWINGS

For a fuller understanding of the nature and advantages of this invention, as well as the preferred mode of use, reference should be made to the following detailed description read in conjunction with the accompanying drawings which are not to scale.

FIG. 1 is a schematic view of a perpendicular magnetic tunnel junction (pMTJ) element as an example of a two terminal resistive switching element that can be used in a memory array.

FIG. 2 is a schematic illustration of a two terminal resistive switching element connected with word and bit lines and connected with a source-line selector.

FIG. 3 is a view of a portion of a vertical channel selector.

FIG. 4 is a cross sectional view of a memory cell as viewed from line 4-4 of FIG. 3.

FIG. 5 is a top-down, cross-sectional view of a memory channel selector as viewed from line 5-5 of FIG. 3.

FIGS. 6-25 are views of a magnetic memory array in various intermediate stages of manufacture in order to illustrate a method for forming a memory array according to an embodiment;

FIG. 26 is a perspective view of a memory array according to an alternate embodiment.

FIG. 27 is a cross sectional view of a portion of the memory array of FIG. 26.

### DETAILED DESCRIPTION

The following description is of the best embodiments presently contemplated for carrying out this invention. This description is made for the purpose of illustrating the general principles of this invention and is not meant to limit the inventive concepts claimed herein.

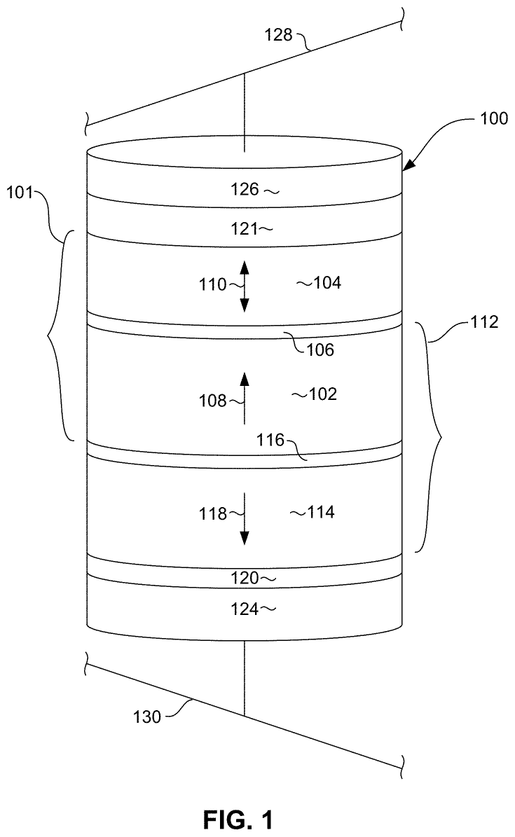

Referring now to FIG. 1, a magnetic memory element 100 can be in the form of a perpendicular magnetic tunnel junction (pMTJ) memory element, which is described as a specific example of a two terminal resistive switching element that can be used in various embodiments. The magnetic memory element can include an MTJ 101 that can include a magnetic reference layer 102, a magnetic free layer 104 and a thin, non-magnetic, electrically insulating barrier layer 106 located between the magnetic reference layer 102, and magnetic free layer 104. The barrier layer 106 can be an oxide such as MgO. The magnetic reference layer has a magnetization 108 that is fixed in a direction that is preferably perpendicular to the plane of the layers as indicated by arrow 108. The magnetic free layer 104 has a magnetization 110 that can be in either of two directions perpendicular to the plane of the layer 104. While the magnetization 110 of the free layer 104 remains in either of two directions perpendicular to the plane of the layer 104 in a quiescent state, it can be moved between these two directions as will be described in greater detail herein below. When the magnetization 110 of the magnetic free layer 104 is in the same direction as the magnetization 108 of the reference layer 102, the electrical resistance across the layers 102, 106, 104 is at a low resistance state. Conversely, when the magnetization 110 of the free layer 104 is opposite to the magnetization 108 of the reference layer 102, the electrical resistance across the layers 102, 106, 104 is in a high resistance state.

The magnetic reference layer 102 can be part of an anti-parallel magnetic pinning structure such as a Synthetic Anti-Ferromagnet (SAF) 112 that can include a magnetic balancing bottom layer 114, and a non-magnetic, antiparallel coupling layer (such as Ru) 116 located between the bottom SAF layer 114 and reference layer 102. The antiparallel coupling layer 116, which will be described in greater detail herein below, can be constructed to have a composition and thickness such that it will couple the layers 114, 102 in an antiparallel configuration. The antiparallel coupling between the layers 114, 102 ensures that the magnetization 108 of the reference layer 102 is fixed in a direction opposite to the direction of magnetization 118 of the bottom SAF layer 114.

A seed layer 120 may be provided near the bottom of the memory element 100 to initiate a desired crystalline structure in the above deposited layers. A capping layer 121 may be provided near the top of the memory element 100 to protect the underlying layers during manufacture, such as during high temperature annealing and from exposure to ambient atmosphere. The capping layer 121 can be constructed of, for example, Ta.

In addition, electrodes 124, 126 may be provided at the bottom and top of the memory element 100. The electrodes 124, 126 may be constructed of a non-magnetic, electrically conductive material such as one or more of Ta, W, Cu and Al and can provide electrical connection a bit line 128 and a word line 130 for reading and writing data to the memory element 100.

The magnetic free layer 104 has a perpendicular magnetic anisotropy that causes the magnetization 110 of the free layer 104 to remain stable in one of two directions perpendicular to the plane of the free layer 104. In a write mode, the orientation of the magnetization 110 of the free layer 104 can be switched between these two directions by applying an electrical current through the memory element 100 from the circuitry 128. A current in one direction will cause the memory element to flip to a first orientation, and a current in an opposite direction will cause the magnetization to flip to a second, opposite direction. For example, if the magnetization 110 is initially oriented in a downward direction in FIG. 1, applying a current in a downward direction through the element 100 will cause electrons to flow in an opposite direction upward through the element 100. The electrons travelling through the reference layer will become spin polarized as a result of the magnetization 108 of the reference layer 102. These spin polarized electrons cause a spin torque on the magnetization 110 of the free layer 104, which causes the magnetization to flip directions.

On the other hand, if the magnetization 110 of the free layer 104 is initially in an upward direction in FIG. 1, applying an electrical current through the element 100 in an upward direction will cause electrons to flow in an opposite direction, downward through the element 100. However, because the magnetization 110 of the free layer 104 is opposite to the magnetization 108 of the reference layer 102, the electrons with an opposite spin will not be able to efficiently pass through the barrier layer 106 to the reference layer 102. As a result, the electrons having an opposite spin will be reflected at barrier layer 106, and return to the free layer 104 with a spin polarization opposite that of the reference layer 102. These spin polarized electrons cause a spin torque that causes the magnetization 110 of the free layer 104 to flip from an upward direction to a downward direction.

The magnetic memory element 100 can be electrically connected with a bit line 128 at one end and a word line 130 at the opposite end. An electrical current from the word and bit lines 128, 130 can be used to switch the memory state of the memory element 100 as described above, and can also be used to read an electrical resistance of the memory element during a read operation to determine whether the memory element 100 is in a high resistance state or a low resistance state (i.e. 0 or 1).

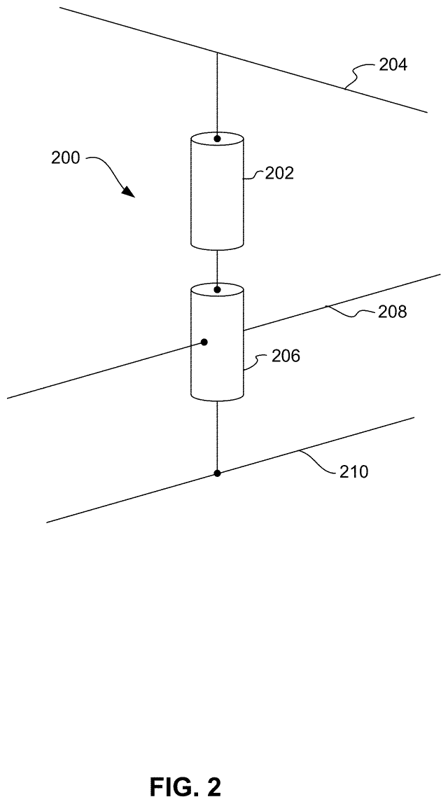

FIG. 2 is a schematic illustration of a memory cell 200 of a memory array. The memory cell 200 includes a two terminal resistive memory element 202. The two terminal resistive memory element 202 can be a magnetic tunnel junction (MTJ) element such as that described above with reference to FIG. 1, or could be some other type of two terminal resistive memory element such as, but not limited to: ReRAM; Correlated Electron RAM (CERAM); Conductive Bridge RAM (CBRAM); or memristor structures. ReRAM can be a resistive switch which can be based on metal filaments such as silver in amorphous silicon. Other types of ReRAM include metal filaments in chalcogenide materials. In addition ReRAM element can be constructed using HfO with a titanium buffer layer. Various forms of tantalum oxide have also been used as an insulator between two metal electrodes. ReRAM can also be based on transition metal oxides (TMO) such as perovskite manganites and titanates. Correlated Electron RAM (CERAM) can be based on transition metal oxides such as perovskite manganites and titanates. Conductive Bridge RAM (CBRAM) can be formed using materials such as silver-doped germanium selenide glasses and copper-doped germanium sulfide electrolytes. Another type of memory element is Phase Change Material (PCM) where a resistance change is effected by changing the morphology of a material form amorphous to crystalline and back again. PCM materials include compounds of Germanium, Antimony and Tellurium such as Ge₂Sb₂Te₅ (GST).

The two terminal resistive memory element can be connected at one end to an electrically conductive bit line 204. The other end of the two terminal resistive memory element 202 can be connected with a selector 206. The selector 206 can be in the form of a vertical semiconductor transistor structure which will be described in greater detail herein below. The selector 206 is connected with a source line 210, which provides a source-line voltage to the selector 206. A word-line 208 is electrically connected with the selector 206 in such a manner as to supply a gate voltage to the selector 206. When the word-line 208 applies a voltage to the selector 206, the selector becomes conductive, allowing a current to flow from the source-line 210 to the memory element 202. When voltage at the word-line 208 is removed, the selector 206 becomes insulating, thereby preventing the flow of current between the source-line 210 and the memory element 202.

Memory systems employing two terminal resistive memory elements such as MTJ memory elements exhibit fundamentally different performance characteristics from more traditional memory systems that employ transistors as memory elements, such as in NAND architectures. In such more traditional transistor-based memory systems, the storage of electrical charge in a location between the transistor's gate and its channel changes the transistor's threshold voltage. The difference between a programmed and erased cell is sensed by measuring the transistor's source-drain current. Programming is done with high voltages but small currents. To get a large window between programmed and erased states, more charge can be stored but this is usually at the expense of other factors such as endurance and retention.

Memory systems based on two terminal memory elements such as MTJ elements, however, function in a fundamentally different manner. The memory element is either in a high resistance state or low resistance state, and the electrical resistance of the memory element is dictated by the magnetic orientations of the magnetizations of the magnetic layers in the memory element. As described above, this memory state is switched (written) by supplying an electrical current through the memory element 202 (e.g. between the source-line 210 and the bit line 204. The higher the current through the memory element 202 the higher the probability is that the memory state of the memory element 202 will be switched as desired. Therefore, increasing this current increases the accuracy of writing by increasing the number of memory elements that will be correctly switched. Ideally, 100% of the memory elements will be switched as desired, and to reach or come close to this performance, ideal an increased electrical current between the source-line 210 and bit-line 204 is desired.

Accurately switching the memory state of the memory element 202 requires that a large electrical current be able to flow through the selector 206 to the memory element 202 when the selector is in an “on” state. This requirement for high current at low voltage shows a fundamental difference between such a system and the more traditional transistor-based systems such as NAND Flash where high voltages and low currents are used to store electrical charge. In a memory system such as that described above, the selector 206 requires high current flow in an “on” state to reliably switch the memory state 202 when desired. This need for increased current flow through the selector 206, therefore, requires a fundamentally different design and structure than with transistor based memory systems. As a result, the formation of such a high current selector transistor fabricated in a manufacturable process has not been previously contemplated by those skilled in the art of memory arrays.

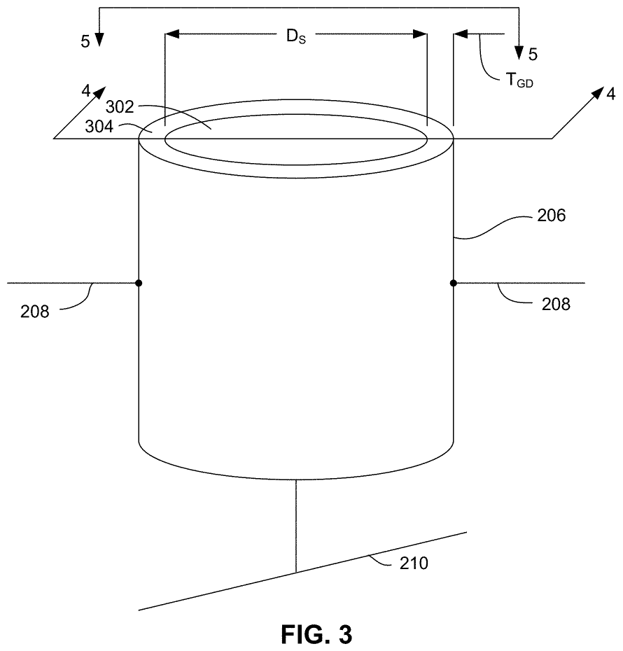

FIG. 3 shows a schematic illustration of a portion of a selector structure 206 that can accommodate a high current flow in an “on” or low resistance state. The selector transistor 202 includes a semiconductor column 302, which can comprise silicon (Si) or some other suitable semiconductor such as Silicon-germanium (Si/Ge), germanium (Ge), Gallium Arsenide (GaAs), Indium-gallium-arsenide (InGaAs), Gallium-Indium-Zinc-Oxide (GIZO). The top and bottom ends of the semiconductor column can be doped, such as with Arsenic or phosphorus, to provide a source and a drain for the selector structure 202. The semiconductor column 302 is circumferentially surrounded by a gate dielectric 304, which can be a material such as silicon oxide or some other suitable dielectric material such as silicon nitride, silicon oxynitride or aluminum oxide or combinations of these.

The semiconductor column 302 has a diameter D_{S} and the gate dielectric 304 has a thickness T_{GD}. Increasing the diameter D_{S} of the semiconductor column effectively increases the amount of current that can flow through the semiconductor column in an “on” state. Therefore, to provide an effective conduction of current through the selector 202 to drive the memory element 202 (FIG. 2), the semiconductor column 302 preferably has a diameter Ds of at least 10 nm. In addition, reducing the thickness T_{GD} of the gate dielectric layer 304 reduce electrical resistance through the semiconductor column when in an “on” state. Therefore, the gate dielectric 304 preferably has a thickness of less than 20 nm.

Another way to increase current flow through the semiconductor column 302 in an “on” state is by carefully controlling the material of which the semiconductor column 302 is constructed. Pure monocrystalline semiconductor has a much higher effective conduction as compared with other structures such as amorphous or polycrystalline semiconductor. To that end, the semiconductor column preferably has a structure that is as close to monocrystalline as possible, although some inclusions or disruptions in the crystalline structure may inevitably occur in the semiconductor column 320. While forming the semiconductor column 302 as a 100% pure monocrystalline structure may not be practical, it is desirable that the semiconductor 302 be as close to pure monocrystalline as possible. For example, the semiconductor column is preferably at least 80 percent monocrystalline by volume, or more preferably at least 90 percent monocrystalline by volume. A novel process for forming such a highly monocrystalline semiconductor column 302 is described herein below.

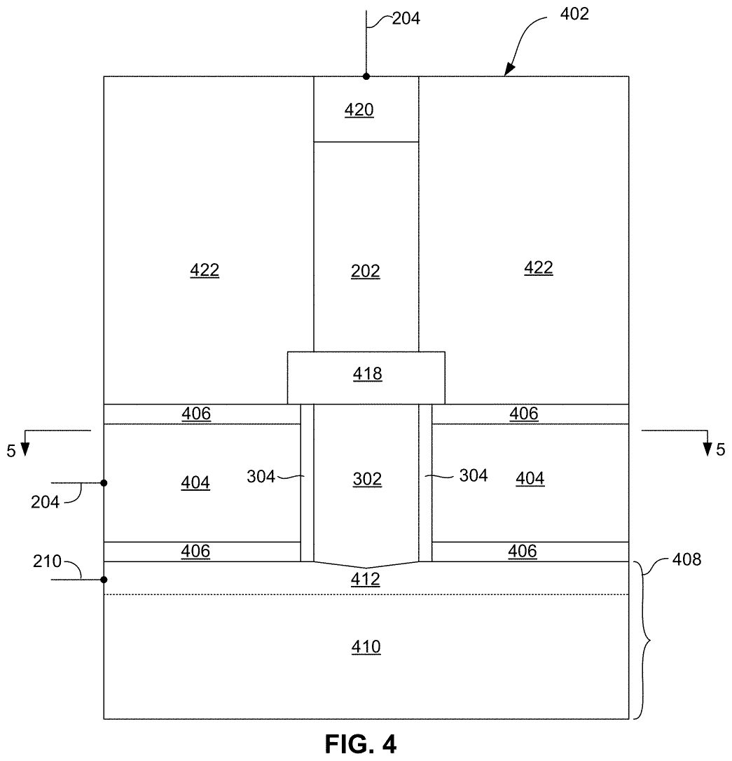

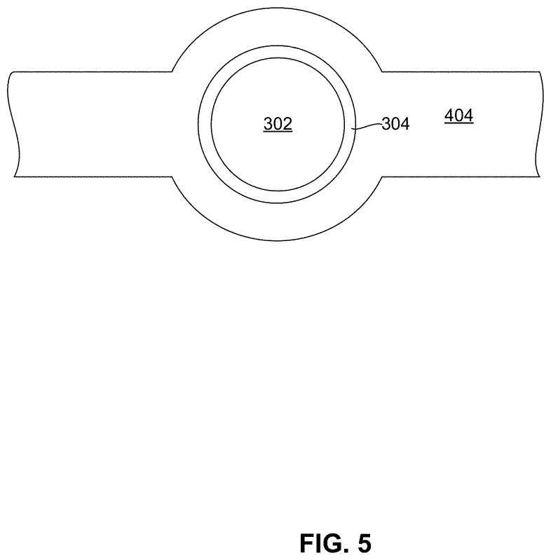

FIG. 4 is a cross-sectional view of a memory cell structure 402 including the selector structure 206 and two terminal resistive memory element 202 according to an embodiment as viewed from line 4-4 of FIG. 3. The selector structure 206 includes the semiconductor column 302 and surrounding gate dielectric 304. An electrically conductive gate material 404 is formed at the side of the selector structure 206. A possible configuration of the gate 404 can be more clearly understood with reference to FIG. 5, which shows a top down view as seen from line 5-5 of FIG. 4. As seen in FIG. 5, the gate layer 404 can be formed so that it surrounds and contacts the gate dielectric layer 304, such that the gate dielectric 304 separates the gate layer 404 from the semiconductor column 302. The gate layer can be a metal such as tungsten or can be a polycrystalline semiconductor such as Si. In addition, the gate layer 404 can be a combination of polycrystalline silicon and a silicide of a metal such as titanium, cobalt, nickel or tungsten. The gate layer can be part of or electrically connected with a word-line 208. Upper and lower dielectric insulation layers 406 (FIG. 4) can be formed above and below the gate layer 404 to electrically isolate the electrically conductive gate layer 404 from surrounding structure. The dielectric insulation layers 406 can he an oxide such as silicon oxide.

The memory element 202 can be formed over the selector structure 206, and can be electrically connected with an end of the semiconductor column 302 by a bottom electrode 418. A top electrode 420 can be formed at the opposite (top) end of the memory element 202 to connect the memory element 202 with the bit line 204. The area surrounding the sides of the memory element can be filled with a dielectric isolation layer 422, which can be an oxide such as silicon oxide or some other suitable material.

The semiconductor pillar structure 302 can be formed on a substrate 408. The substrate 408 can include a substrate base 410 formed of a semiconductor material such as Si or silicon on insulator. A doped region 412 can be formed at the top of the substrate base. The doped region 412 can provide a source line connected with source-line circuitry 210, which will be described in greater detail herein below. It should be pointed out that the doped portion 412, which forms a portion of the source-line, can be formed as a line in the substrate, or could be formed as a source-plane in two dimensions for providing a source line voltage to multiple rows and columns of memory cells.

As discussed above it is desirable that the selector structure 206 be configured to provide a high current flow to the memory element when in a low resistance “on” mode (e.g. when a gate voltage is applied by the gate line 404). Therefore, the dimensions and material composition of the semiconductor column and gate dielectric are preferably configured to maximize this current flow. To this end, the semiconductor column 302 such as shown in FIG. 3 preferably has a diameter D_{S} of at least 10 nm and the semiconductor column comprises a semiconductor material that is as close to monocrystalline as possible, being at least 80 percent monocrystalline and more preferably at least 90 percent monocrystalline. In order to form such a high quality substantially monocrystalline semiconductor column, the semiconductor column can be an epitaxial semiconductor formed by selective epitaxial growth on the semiconductor substrate 408. As shown in FIG. 4, in order to facilitate this selective epitaxial growth, the semiconductor column 302 is recessed into the substrate 408 to a location within the doped region 412 to ensure that the semiconductor column 302 is formed on crystalline semiconductor substrate material below any naturally occurring oxide of the semiconductor substrate 408. Also, as can be seen in FIG. 4, the substrate 408 is formed with a recessed, beveled shape at its bottom whereon the semiconductor column 302 is formed. This configuration will be better understood upon further discussion of a method for manufacturing such a memory structure using selective epitaxial semiconductor growth as described herein below. In addition, as seen in FIG. 3, the gate dielectric layer 304 has a thickness T_{GD}, that is preferably less than 20 nm in order to ensure good electrical conduction when a gate voltage is applied via the gate layer 404 (FIG. 4).

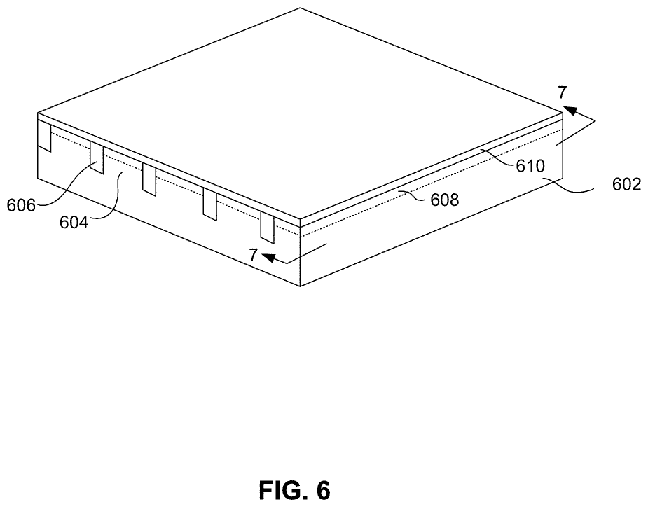

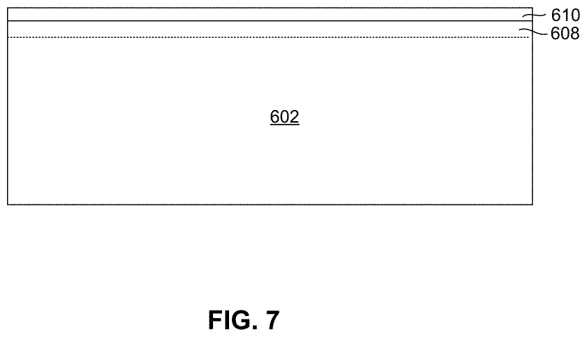

FIGS. 6-25 show a memory array structure in various intermediate stages of manufacture in order to illustrate a method for manufacturing a memory array according to an embodiment of the invention. With particular reference to FIG. 6, a semiconductor substrate 602 is provided. The substrate 602 can be of various materials such as Si or silicon-on-insulator. A masking and etching process can be performed on the semiconductor substrate 602 to form diffusion lines 604 separated by isolation trenches 606. The isolation trenches 606 can be filled with a dielectric material by depositing a dielectric material into the trenches and then performing a chemical mechanical polishing (CMP). An upper portion of the substrate can be doped to form an upper doped region 608 that can provide a source-line as will be seen. A first dielectric layer 610 is deposited over the substrate 602. The dielectric layer 610 can be an oxide such as silicon oxide. FIG. 7 shows a side cross sectional view as seen from line 7-7 of FIG. 6, showing a plane parallel with the diffusion lines 604.

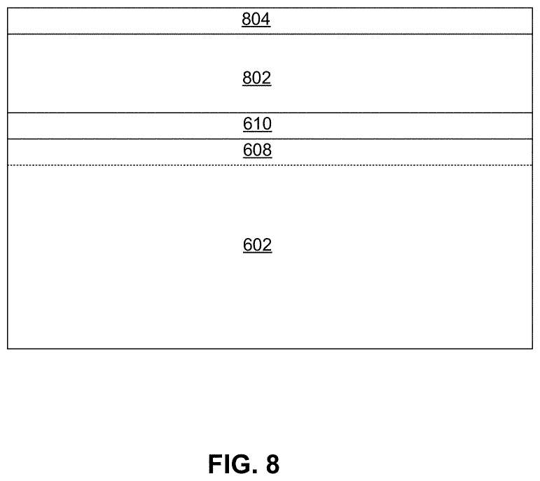

With reference now to FIG. 8, an electrically conductive layer 802 is deposited over the thin oxide layer 610. The electrically conductive layer 802 can be a material such as doped polysilicon or a refractory metal such as tungsten, tungsten nitride or titanium nitride, and can provide a word-line as will be seen. Then, a second dielectric layer 804 can be deposited over the electrically conductive layer 802.

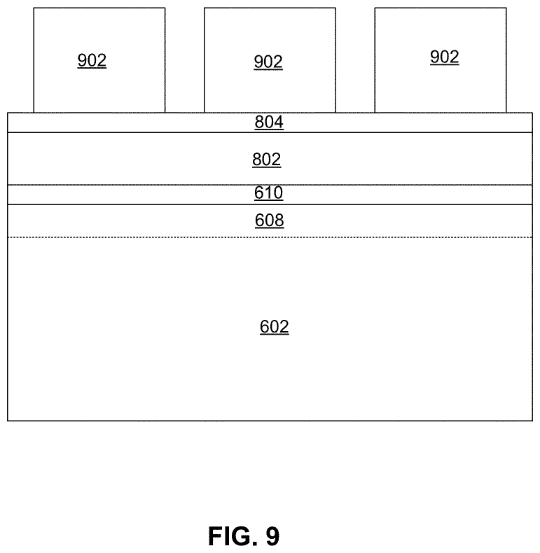

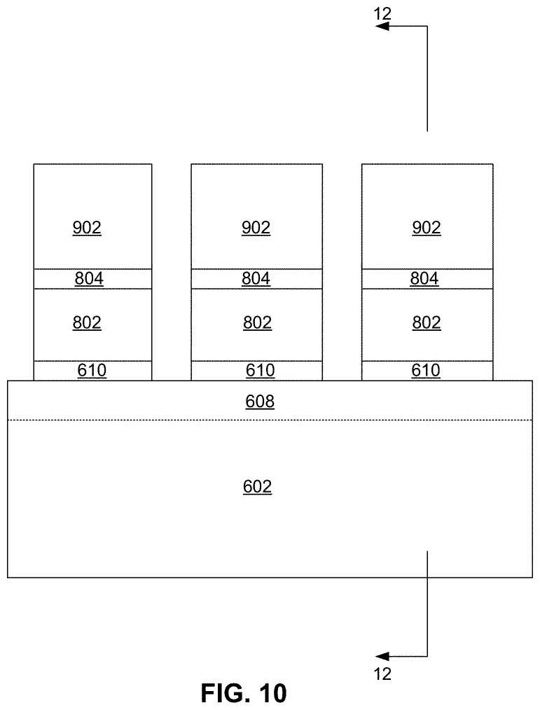

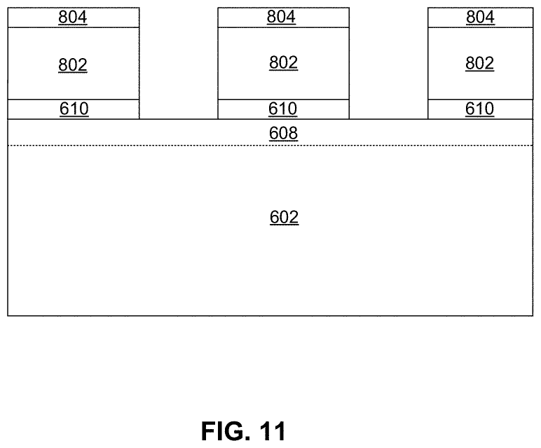

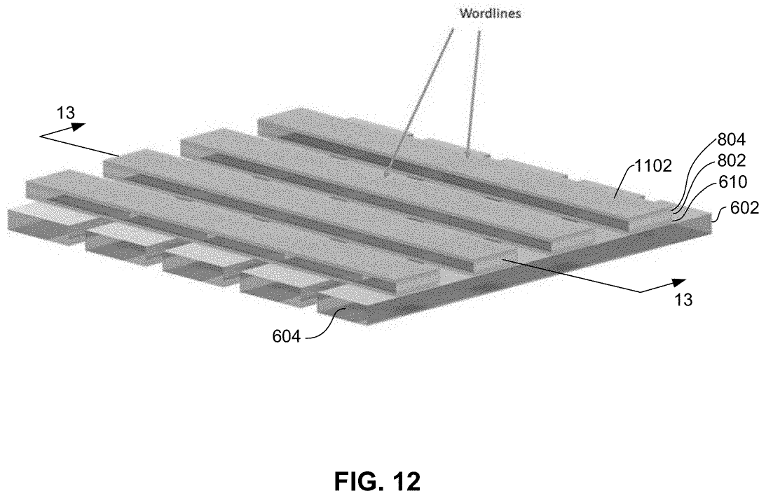

With reference to FIG. 9, a mask structure 902 can be formed over the second dielectric layer 804. The mask is configured to define a plurality of word-lines, having spaces where material will be removed between the word-lines. An etching process such as reactive ion etching can then be performed to remove material not protected by the mask, leaving a structure as seen in FIG. 10. After performing the etching to produce a plurality of word-lines the mask 902 can be removed, such as by chemical liftoff or some other suitable process, leaving a structure as shown in FIG. 11, with a plurality of word-lines 1102. The resulting word lines 1102 can be seen more clearly with reference to FIG. 12, which shows a perspective view of the substrate 602 and word-lines 1102 formed thereon. Note that the isolation structures 606 in FIG. 6 are omitted for clarity.

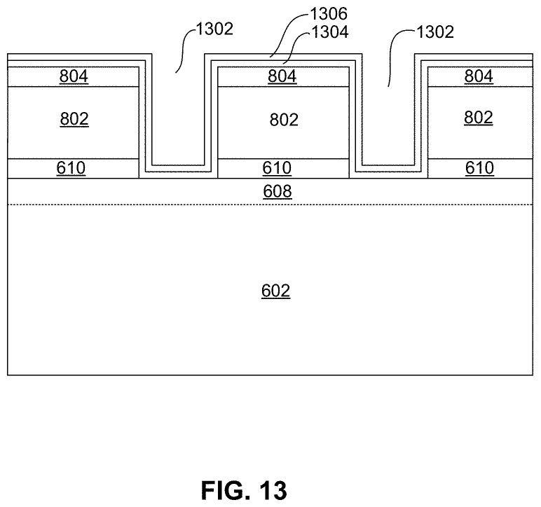

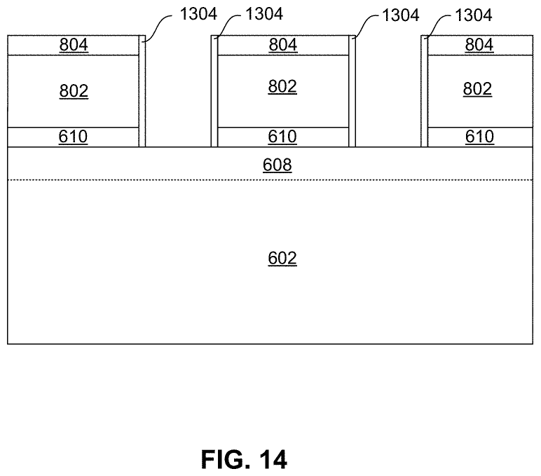

FIG. 13 shows a cross-section along a plane parallel with the word-lines 1102, such as seen from line 13-13 of FIG. 12 after holes in the word-lines have been formed as follows. A mask structure (not shown) is formed over the word lines 1102, the mask having openings such as circular openings or some other shape. An etching process is then performed to remove portions of the word line structures 1102 leaving openings 1302 in the word-lines, shown in cross-section in FIG. 13. A layer of gate dielectric material 1304 is then formed, followed by a protective layer 1306. The gate dielectric layer 1304 can be an oxide such as silicon oxide and can be formed using Atomic Layer Deposition. The protective layer 1306 can be a material such as amorphous silicon. A directional etching process such as ion milling can then be performed to remove portions of the material 1304, 1306 primarily from the bottom of the openings. Then, a selective etching process such as reactive ion etching can be performed to remove the remaining protective layer, leaving the gate dielectric layer 1304 intact. This leaves a structure as shown in FIG. 14.

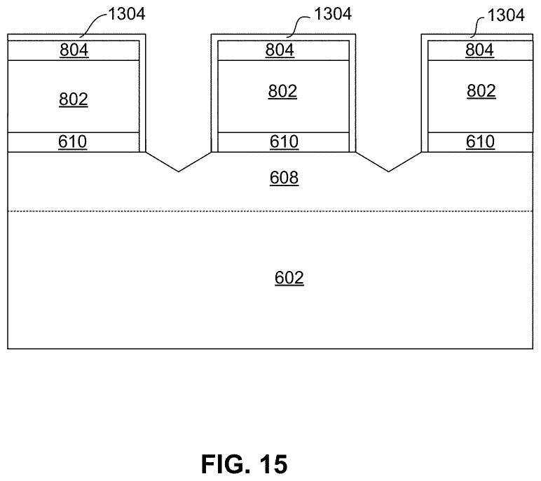

With reference now to FIG. 15, an etching process is performed to etch into the semiconductor substrate as shown. This etching process removes any naturally occurring oxide from the semiconductor material to reveal a monocrystalline semiconductor surface at the bottom of the opening. Preferably, the etching process results in a beveled bottom surface as shown. This beveled shape of the exposed crystalline semiconductor surface facilitates selective epitaxial growth of semiconductor material with a mono-crystalline or nearly mono-crystalline structure.

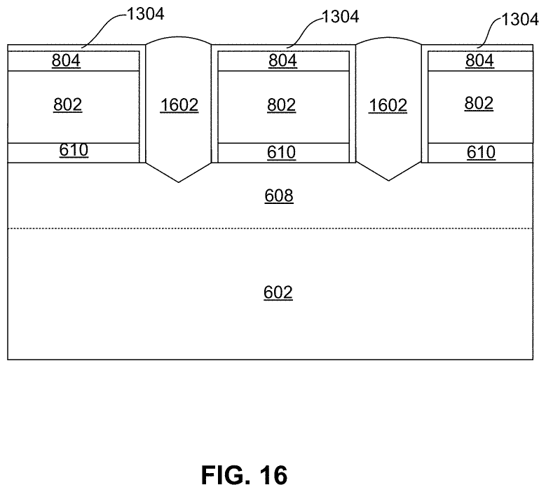

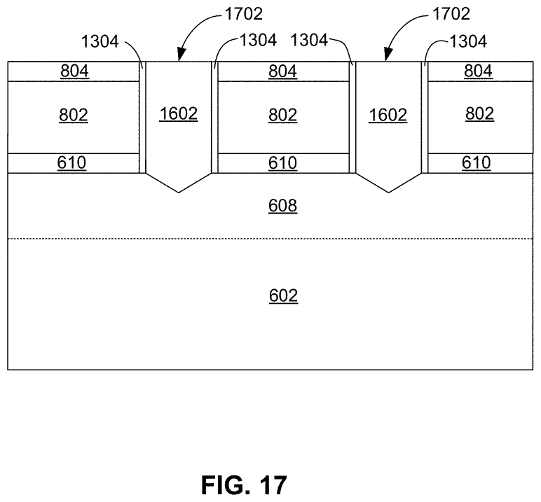

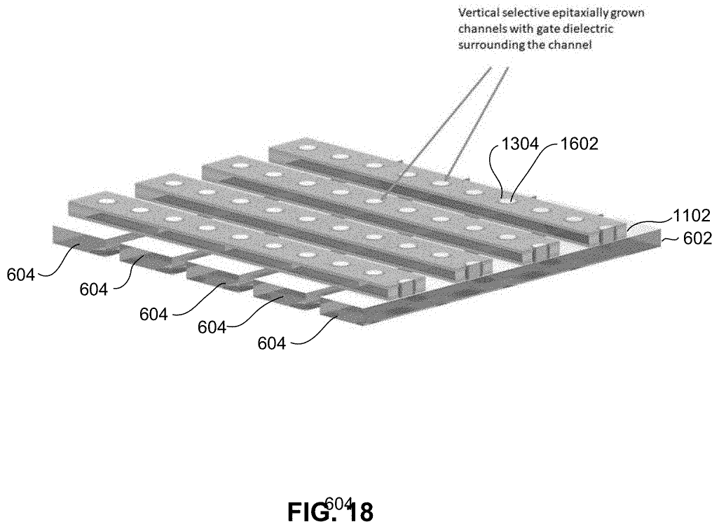

With reference now to FIG. 16, a semiconductor material 1602 is grown into the openings on the exposed surface of the semiconductor substrate 602 and 608 by selective epitaxial growth. Selective epitaxial growth allows for growth of semiconductor material only on the etched surface where any semiconductor oxide has been removed. In this case, the semiconductor material grows only on the exposed, etched surface of the semiconductor substrate 602 and 608 at the bottom of the openings. This selective epitaxial growth of semiconductor material allows the semiconductor 1602 to be essentially monocrystalline. While some imperfections in the crystalline lattice may inevitably appear in the crystalline structure of the semiconductor 1602, the grown structure 1602 will be as close to mono-crystalline as possible. For example, the crystalline structure of the epitaxially grown semiconductor can be at least 80% monocrystalline or more preferably at least 90% monocrystalline. As seen in FIG. 16, the epitaxially grown semiconductor material 1602 may extend slightly out of the openings previously formed in the gate structure 1102. A chemical mechanical polishing can then be performed to planarize the structure and remove excess semiconductor 1602, leaving a structure as shown in FIG. 17. The semiconductor column 1602, gate dielectric 1304 and electrically conductive gate 802 together form a vertical transistor selector 1702. When a voltage is applied at the gate layer 802, the semiconductor column 1602 becomes electrically conductive, allowing current to flow through the semiconductor column 1602, vertically as shown in FIG. 17. Because the semiconductor column 1602 is formed by selective epitaxy so as to be substantially monocrystalhne, the semiconductor column 1602 can have a very low resistance and can effectively conduct a large amount of current when in an “on” state. This ability to efficiently conduct electrical current can be further enhanced by controlling the dimensions of the selector transistor structure 1702. For example, increasing the perimeter of the semiconductor column 1602, and decreasing the thickness of the gate dielectric layer 1304 can effectively increase the amount of current that can flow through the semiconductor column 1602 in an “on” state. FIG. 18 shows a perspective view showing how the resulting gate structure and semiconductor pillar structure can look relative to the previously formed diffusion lines formed in the semiconductor substrate 602 and 608.

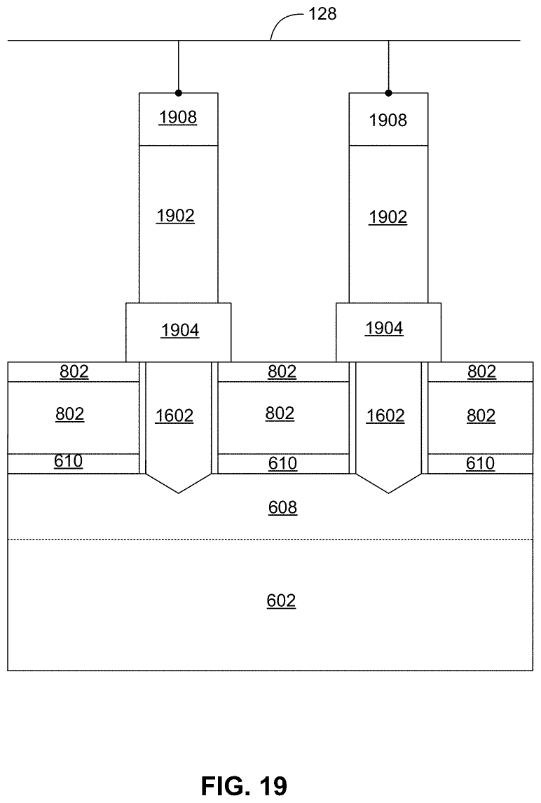

With reference now to FIG. 19, a two terminal resistive memory element 1902 can be formed so as to be electrically connected with the semiconductor column 1602 of the selector structure 1702. In one embodiment, the two terminal resistive memory element can be a magnetic tunnel junction such as the perpendicular magnetic tunnel junction (pMTJ) 100 described above with reference to FIG. 1. Alternatively, the two terminal resistive memory element could be some other type of memory element, such as but not limited to: ReRAM; Correlated Electron RAM (CERAM); Conductive Bridge RAM (CBRAM); or memristor structures. ReRAM can be a resistive switch which can be based on metal filaments such as silver in amorphous silicon. Other types of ReRAM include metal filaments in chalcogenide materials. In addition ReRAM element can be constructed using HfO with a titanium buffer layer. Various forms of tantalum oxide have also been used as an insulator between two metal electrodes. ReRAM can also be based on transition metal oxides (TMO) such as perovskite manganites and titanates. Correlated Electron RAM (CERAM) can be based on transition metal oxides such as perovskite manganites and titanates. Conductive Bridge RAM (CBRAM) can be formed using materials such as silver-doped germanium selenide glasses and copper-doped germanium sulfide electrolytes.

The two terminal resistive memory element 1902 can be electrically connected with the semiconductor column 1602 by an electrically conductive bottom electrode 1904. The electrically conductive bottom electrode 1904 can be constructed of a material such as Ta or some other electrically conductive metal. Other electrically conductive structures such as electrically conductive vias (not shown) may also be included to provide electrical connection between the two terminal memory element 1902 and the semiconductor column 1602, such as between the bottom electrode 1904 and the semiconductor column 1602. An upper electrode 1908 can be electrically connected with the two terminal resistive memory element 1902 at the end opposite the bottom electrode 1904. The upper electrode 1908 can provide electrical connection between the two terminal resistive memory element 1902 and the bit line 128 previously described.

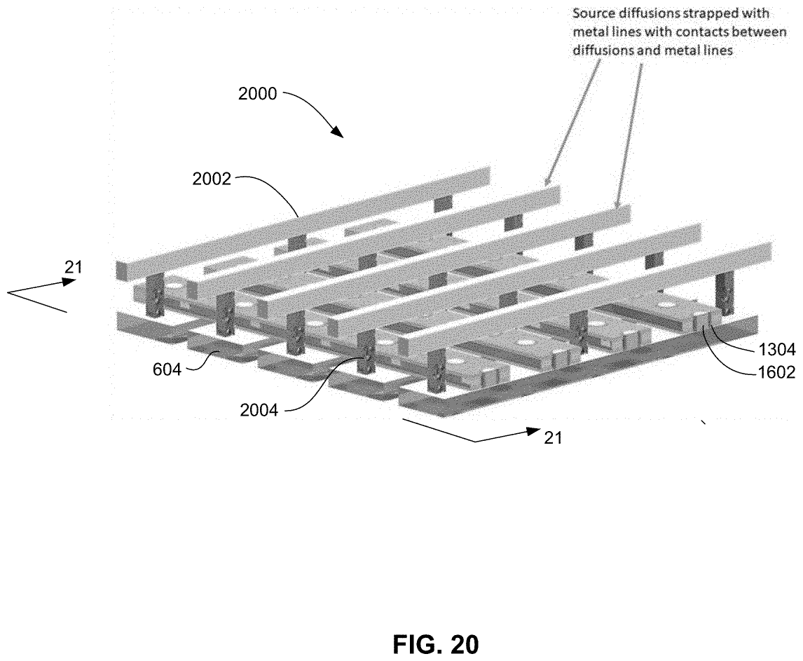

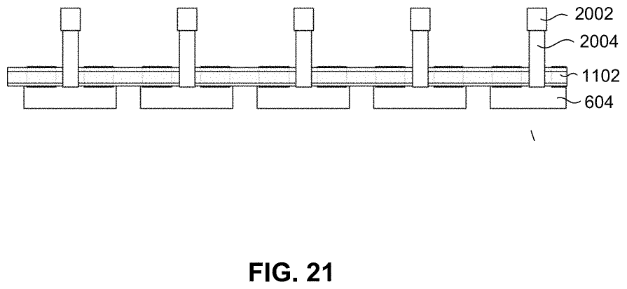

FIG. 20 shows a perspective view of a memory array 2000. The memory array 2000 can include a memory array structure such as previously described with reference to FIG. 18, having source diffusion lines 604 and gate structures 1102 with vertical transistor selector features with vertical semiconductors 1602 and gate dielectric layers 1304 formed therein. As shown in FIG. 20, the memory array 2000 can include metal lines 2002, which can be electrically connected with the source diffusion lines 604 by electrically conductive vias 2004, which can be constructed of a suitable, electrically conductive metal. The metal lines 2002 can be connected with associated circuitry (not shown) for providing an electrical source current to the source diffusion lines 604. FIG. 21 shows a cross-sectional view as seen from line 21-21 of FIG. 20 wherein the connection between source diffusion lines 604, electrically conductive vias 2004 and metal lines 2002 can be seen more clearly. Note that isolation regions 606 as shown in FIG. 6 have been omitted for clarity.

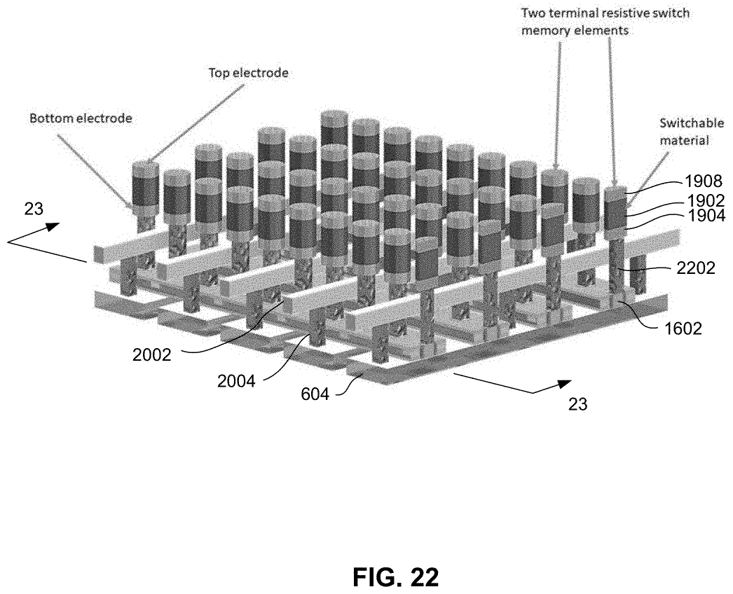

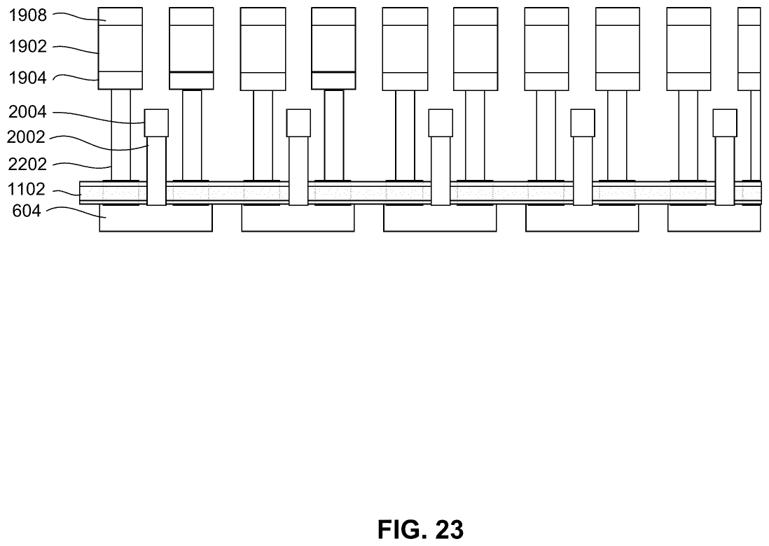

FIG. 22 shows a perspective view of the memory array 2000 of FIG. 20 with added two terminal resistive memory elements 1902. The two terminal resistive memory elements 1902 are electrically connected with upper and lower electrodes 1908, 1904. As shown in FIG. 22, the two terminal resistive memory elements 1902 and electrodes 1904 can be electrically connected with selectors 1602 by electrically conductive vias 2202. The electrically conductive vias 2202 can be constructed of a suitable electrically conductive metal such as tungsten or a combination of tungsten and tungsten nitride. FIG. 23 shows a cross-sectional view of the structure of FIG. 22 as seen from line 23-23 of FIG. 22 in order to more clearly see the connection of the memory elements 1902 with the channel selector 1602 through the vias 2202.

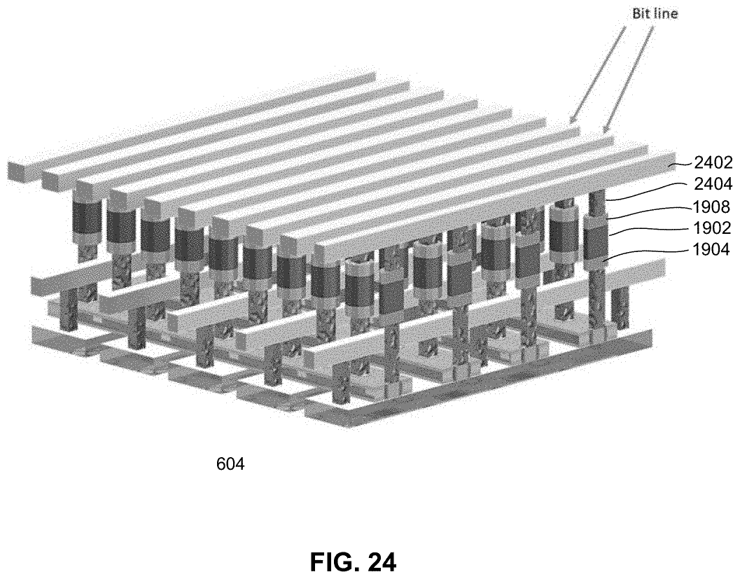

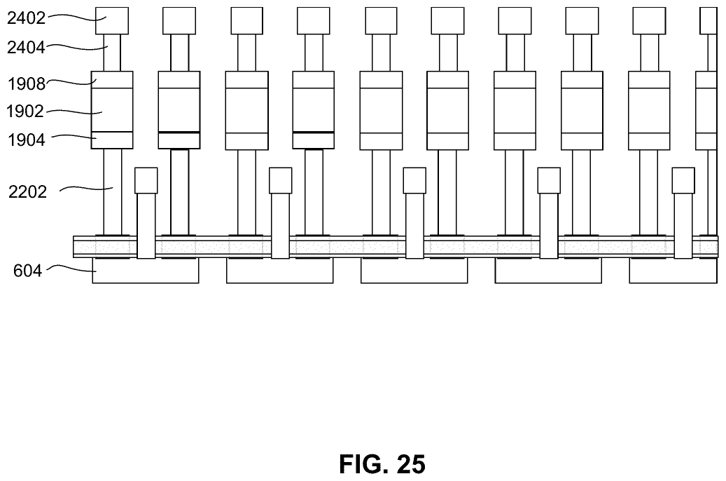

FIG. 24 shows how electrically conductive bit lines 2402 can be connected with the upper electrode 1908 and with the two terminal resistive memory element 1902 through electrically conductive vias 2404. Again, the vias 2404 can he constructed of a suitable electrically conductive metal. FIG. 25 is a cross sectional view, more clearly showing the connection of the two terminal resistive memory elements 1902 with the bit lines 2402 through the vias 2404.

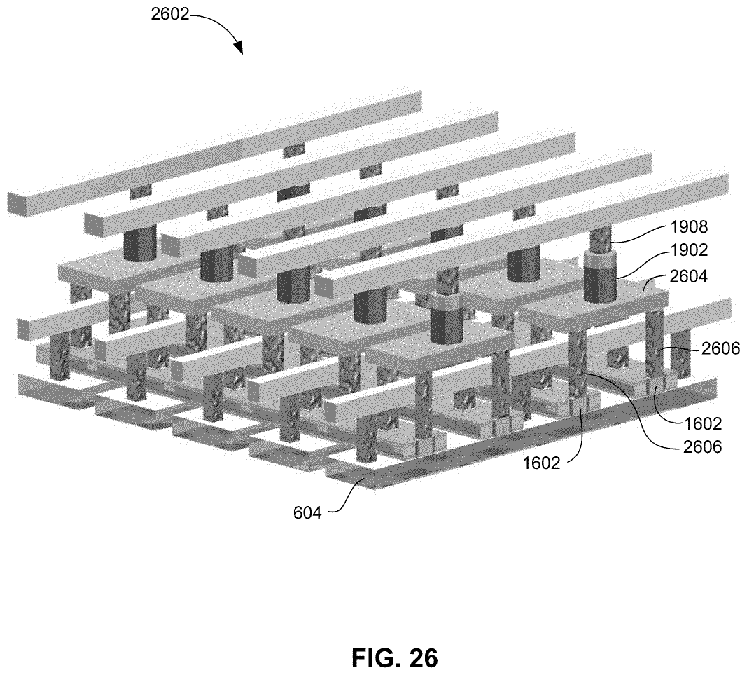

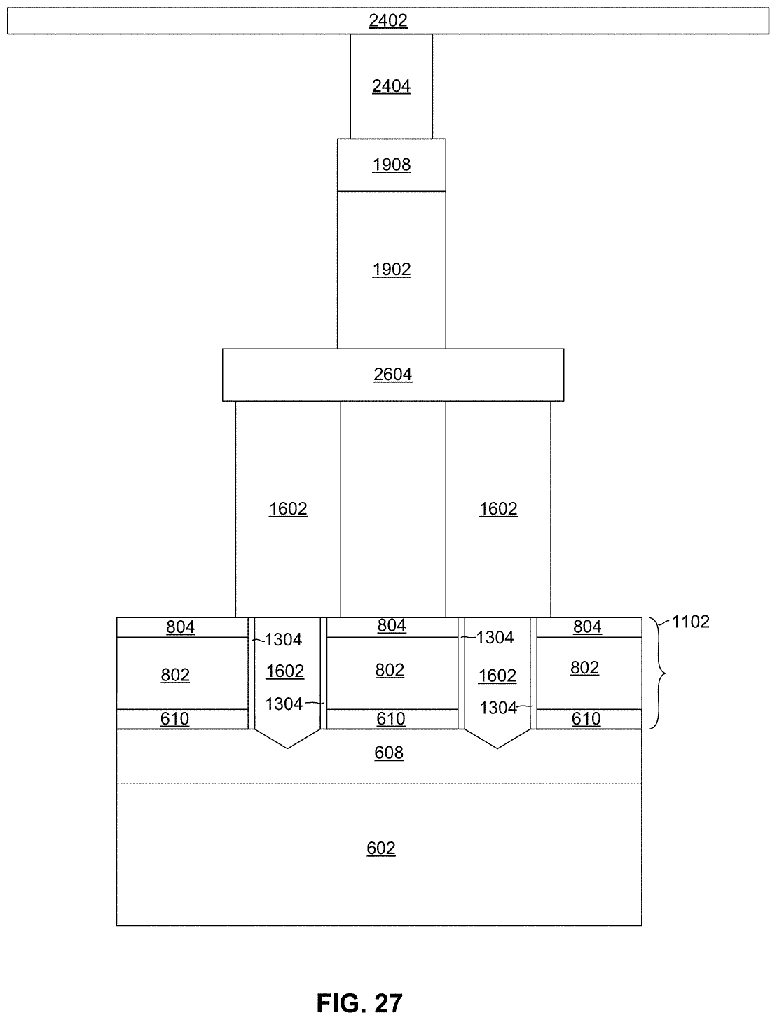

FIGS. 26 and 27 illustrate a memory array 2602 according to an alternate embodiment. FIG. 26 is a perspective view of the memory array and FIG. 27 is a cross sectional view. In some cases, a two terminal resistive memory element may require more switching current than can be provided by a single vertical transistor selector structure. In the embodiment shown in FIGS. 26 and 27, a single two terminal resistive memory element 1902 is connected with two or more selector structures 1602. As shown in FIG. 26, the memory array 2602 includes a plurality of electrically conductive electrodes that extend laterally to connected with multiple selectors 1602. The electrode 2604 can be arranged similar to the previously described bottom electrode 1904 (FIG. 25), but are configured to extend outward to allow connection with multiple selectors 1602. Connection between the electrode 2604 and the plurality of selectors 1602 can be by way of vias 2606, which can be constructed of an electrically conductive metal. Although FIGS. 26 and 27 illustrate electrodes 2604 as connecting a single two terminal resistive memory element with two selectors, this is by way of example. Depending upon design requirements the electrode 2604 could be configured to connect a two terminal memory element with more than two selectors 1602.

While various embodiments have been described above, it should be understood that they have been presented by way of example only and not limitation. Other embodiments falling within the scope of the invention may also become apparent to those skilled in the art. Thus, the breadth and scope of the inventions should not be limited by any of the above-described exemplary embodiments but should be defined only in accordance with the following claims and their equivalents.

What is claimed is:

1. A memory array, comprising:
a semiconductor substrate having a recess formed in its surface;
a selector transistor formed on the substrate, the selector transistor comprising a semiconductor column extending from the recess formed in the substrate, a gate dielectric layer surrounding at least a portion of the semiconductor column, and an electrically conductive gate structure arranged such that the gate dielectric is between the electrically conductive gate structure and the semiconductor column; and
a two terminal resistive memory element electrically connected with the selector transistor.

2. The memory array as in claim 1, wherein the semiconductor column is substantially monocrystalline.

3. The memory array as in claim 1, wherein the semiconductor column is at least 80 percent monocrystalline by volume.

4. The memory array as in claim 1, wherein the semiconductor column is at least 90 percent monocrystalline by volume.

5. The memory array as in claim 1, wherein the notch formed in the surface of the semiconductor substrate has a beveled shape.

6. The memory array as in claim 1, wherein the notch formed in the surface of the substrate has an upper surface that is monocrystalline semiconductor material.

7. The memory array as in claim 1, wherein the semiconductor column has a diameter of at least 10 nm.

8. The memory array as in claim 1, where the gate dielectric has a thickness of no greater than 20 nm.

9. The memory array as in claim 1 further comprising multiple selector transistor structures connected in parallel to the two terminal resistive memory element.

10. The memory array as in claim 1 further comprising a source-line formed in the semiconductor substrate, wherein the electrically conductive gate structure is connected with word-line circuitry and further comprising a bit line electrically connected with the two terminal resistive memory element at an end opposite the selector transistor.

11. The memory array as in claim 1, wherein the two terminal resistive memory array is a perpendicular magnetic tunnel junction.

12. The memory array as in claim 1, wherein the two terminal resistive memory element is a ReRAM element.

13. The memory array as in claim 1, wherein the two terminal resistive memory element is a CBRAM element.

14. The memory array as in claim 1, wherein the two terminal resistive memory element is a CERAM element.

15. The memory array as in claim 1, wherein the two terminal resistive memory element is a phase change memory element.

16. A method for manufacturing a memory array comprising:
providing a semiconductor substrate;
depositing a gate structure over the semiconductor substrate, and forming one or more openings in the gate structure;
forming a gate dielectric layer on an inner surface of the one or more openings;
etching a recess into the semiconductor substrate sufficiently to remove any oxide from the semiconductor substrate in a region exposed through the one or more openings; and
forming a semiconductor column on the etched recess of the semiconductor substrate, the semiconductor column being formed by selective epitaxial growth.

17. The method as in claim 16, further comprising after forming the semiconductor column forming a two terminal resistive memory element, the two terminal resistive memory element being electrically connected with the semiconductor column.

18. The method as in claim 16, wherein the two terminal resistive memory element is a phase change magnetic tunnel junction element.

19. The method as in claim 16, wherein the two terminal resistive memory element is a ReRAM element, CBRAM element, CERAM element phase change memory element.
